(19) United States
(12) Patent Application Publication
(10) Pub. No.: US 2005/0055614 A1
(43) Pub. Date: Mar. 10, 2005

(54) MULTI-CLOCK DOMAIN LOGIC SYSTEM AND RELATED METHOD

(76) Inventor: Ta-Chia Yeh, Hsin-Chu City (TW)

Correspondence Address: (NAIPC) NORTH AMERICA INTERNATIONAL PATENT OFFICE, P.O. BOX 506, MERRIFIELD, VA, 22116, US

(21) Appl. No.: 10/709,922

(22) Filed: Jun. 7, 2004

(30) Foreign Application Priority Data
Sep. 10, 2003 (TW) 092125074

(51) Int. Cl. G01R 31/28

(52) U.S. Cl. 714/726

(57) ABSTRACT

A multi-clock domain logic system includes a plurality of clock domains corresponding respectively to a plurality of clock signals and comprises at least one flip-flop group per each. When a scanning test is executed, a scanning test clock signal is asynchronously input into the flip-flop groups in a predetermined sequence to form a clock signal of the flip-flop groups.

### BACKGROUND OF INVENTION

1. Field of the Invention

The present invention relates to a multi-clock domain logic system, and more specifically, to a multi-clock domain logic system integrating logic operation and scanning test.

2. Description of the Prior Art

Digital logic circuits are widely used in various electronic products. Generally, digital logic circuits include combinational circuits and sequential circuits. A combinational circuit generates output signal(s) according to current input signal(s), and a sequential circuit generates output signal(s) according to previous input signal(s).

A combination of elements operating according to the same clock signal and/or clock signals at the same frequency is called a clock domain. Some digital logic circuits require over two clock domains operation synchronously. These digital logic circuits include over two clock domains, and elements in each clock domain use clock signals at specific frequency for synchronization.

While designing and manufacturing digital logic circuits, a proper device for circuit debug and test is required. A conventional method for testing a digital logic circuit involves connecting a plurality of flip-flop scan units (or scan flip-flops) serially to form a scan chain. Specific logic values are then input into the scan chain for circuit debug. This method is called a scanning test.

Please refer to FIG. 1 showing a conventional multi-clock domain logic system. The multi-clock domain logic system 100 in FIG. 1 includes a first clock domain 110 for receiving a first clock signal CLK1 and a second clock domain 150 for receiving a second clock signal CLK2. The first clock domain 110 includes a first flip-flop group 118, a second flip-flop group 120, and a first logic gate group 112. During logic operation, a mode signal TEST_MODE is set to be 0, the first flip-flop group 118 operates according to the first clock signal CLK1, the first logic gate group 112 generates a first logic signal LOG1 according to the first clock signal CLK1, and the first logic signal LOG1 is used as a clock signal for the second flip-flop group 120 through a second multiplexer 116. During the scanning test, the mode signal TEST_MODE is set to be 1, and a test clock signal TEST_CLK is used as clock signal for the first flip-flop group 118 and the second flip-flop group 120 through the first multiplexer 114 and the second multiplexer 116. Please notice that the test clock signal TEST_CLK can be an independent clock signal for the scanning test only or, as shown in FIG. 1, can be the first clock signal CLK1 or the second clock signal CLK2.

This kind of system structure faces at least two main problems. The first main problem is that during the scanning test, every flip-flop of the four flip-flop groups is controlled by TEST_CLK, so that when TEST_CLK is in transition, every flip-flop is triggered simultaneously. This makes the instantaneous power consumption of the system too large. Furthermore, if the power consumption exceeds the system power plan under normal operation mode (i.e. logic operation mode), the chip in test may be damaged.

The second problem is that since the length of transmission paths of the test clock signal TEST_CLK to each flip-flop group differs from each other, a clock skew may occur and the test clock signal TEST_CLK cannot be input simultaneously into each flip-flop group. This may cause an error during the scanning test to occur.

### SUMMARY OF INVENTION

It is therefore a primary objective of the present invention to provide a multi-clock domain logic system including one or more delay devices to solve the problems mentioned above.

Briefly summarized, a multi-clock domain logic system includes a plurality of clock domains corresponding respectively to a plurality of clock signals and comprising at least one flip-flop group per each clock domain. When a scanning test is executed, a scanning test clock signal is input into the flip-flop groups asynchronously in a predetermined sequence to form a clock signal of the flip-flop groups.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 illustrates a conventional multi-clock domain logic system.

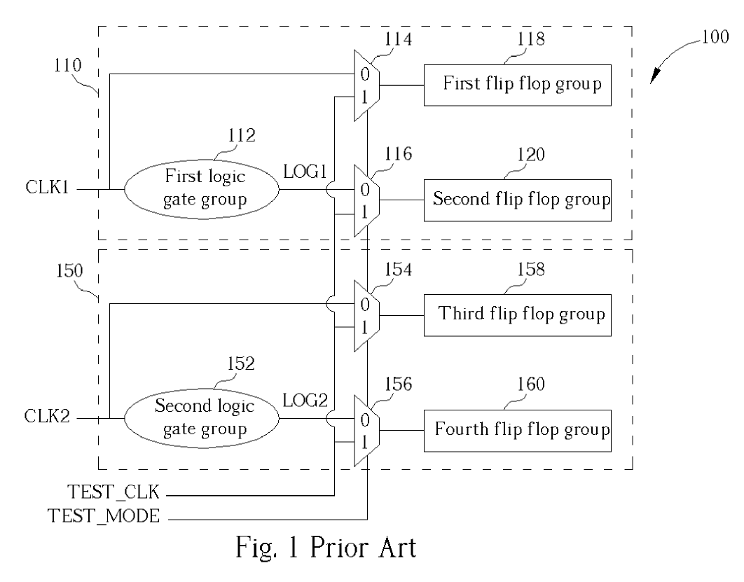

FIG. 2 illustrates a multi-clock domain logic system according to the first embodiment of the present invention.

FIG. 3 illustrates a multi-clock domain logic system according to the second embodiment of the present invention.

### DETAILED DESCRIPTION

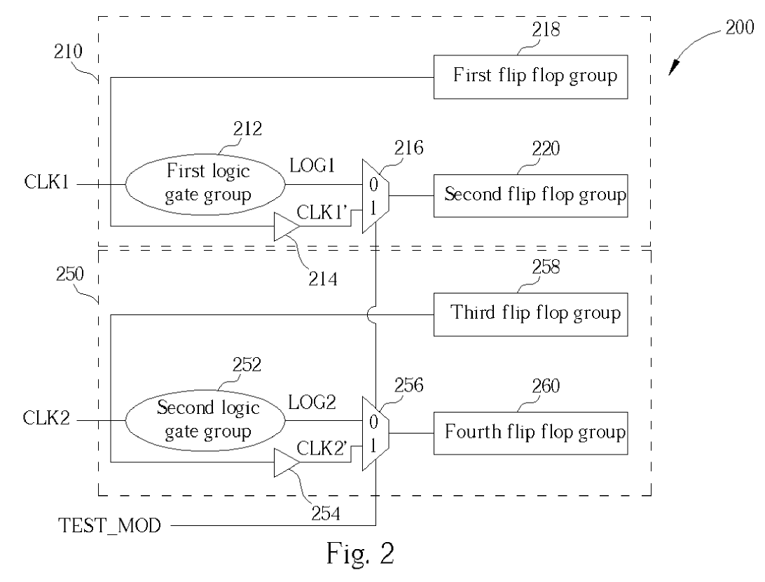

Please refer to FIG. 2 showing a multi-clock domain logic system according to the first embodiment of the present invention. The multi-clock domain logic system 200 in FIG. 2 includes a first clock domain 210 and a second clock domain 250. The first clock domain 210 includes a first flip-flop group 218, a second flip-flop group 220, and a first logic gate group 212. During a logic operation, a mode signal TEST_MODE is set to be 0, the first flip-flop group 218 operates according to a first clock signal CLK1, the first logic gate group 212 generates a first logic signal LOG1 according to the first clock signal CLK1, and the first logic signal LOG1 is used as a clock signal of the second flip-flop group 220 through a multiplexer 216.

During a scanning test, the mode signal TEST_MODE is set to be 1. In this case, to prevent the instantaneous power consumption of the multi-clock domain logic system 200 from being too large, a first delay device 214 and a second delay device 254 are installed in front of the multiplexers 216, 256. Thus, during the scanning test, the first clock domain 210 comprises the first flip-flop group 218 operating according to the first clock signal CLK1 and the second clock domain operating according to a first delayed signal CLK1″. The first delayed clock signal CLK1″ is generated by delaying the first clock signal CLK1 for a period of time with the first delay device 214 and then outputting the signal into the second flip-flop group 220. Since the first delayed clock signal CLK1′ is not synchronous with the first clock signal CLK1, the excessive instantaneous power consumption of the first clock domain 210 and the second clock domain 250 does not occur. In addition, the first clock signal CLK1 and the second clock signal CLK2 can be alternately separated so that the clock signals of the four flip-flop groups are not synchronous. In this way, the instantaneous power consumption of the system as a whole will not be too large.

In the system structure described above, during the scanning test, each clock domain operates basically according to the clock signal (or the delayed clock signal) for the particular clock domain. However, the system structure disclosed by the present invention can also be applied to the case that a plurality of clock domains which operate according to a specific test clock signal (or delayed test clock signals). A further description is as follows.

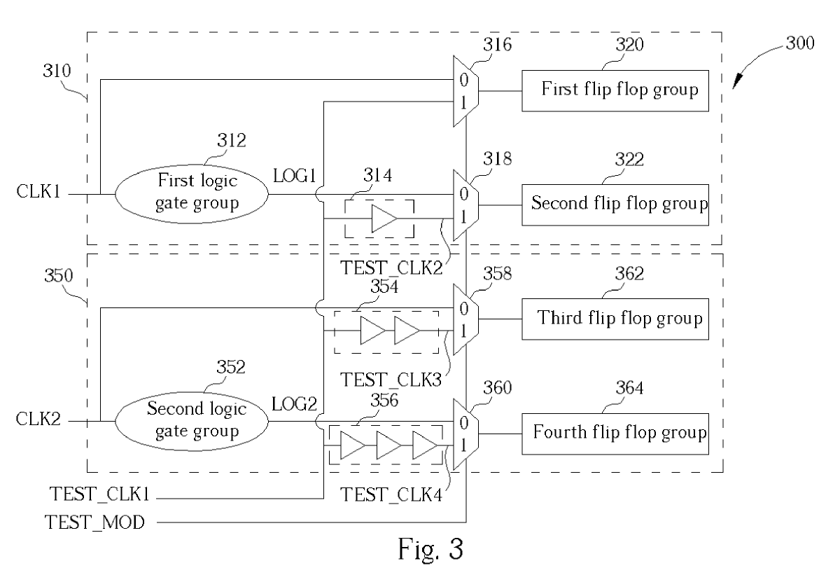

Please refer to FIG. 3 showing a multi-clock domain logic system 300 according to the second embodiment of the present invention. The multi-clock domain logic system 300 includes a first clock domain 310 and a second clock domain 350. During a logic operation, a mode signal TEST_MODE is set to be 0; and a first flip-flop group 320, a second flip-flop group 322, a third flip-flop group 362, and a fourth flip-flop group 364 operate according to a first clock signal CLK1, a first logic signal LOG1, a second clock signal CLK2, and a second logic signal LOG2 respectively.

During a scanning test, the mode signal TEST_MODE is set to be 1. In this case, to prevent the instantaneous power consumption of the multi-clock domain logic system 300 from being too large, a first delay chain 314, a second delay chain 354, and a third delay chain 360 are installed in front of the multiplexers 316, 358, 360 respectively. The number of delay devices in the second delay chain 354 exceeds the number in the first delay chain 314, and the number of delay devices in the third delay chain 356 exceeds the number in the second delay chain 354. Thus, during the scanning test, a first test signal TEST_CLK1, a second test signal TEST_CLK2, a third test signal TEST_CLK3, and a fourth test signal TEST_CLK4 are not synchronous with each other, so that the four flip-flop groups do not operate synchronous and the instantaneous power consumption of the system as a whole will not be too large.

It should be noted that for the convenience of describing various embodiments of the present invention, only two clock domains are shown in FIG. 2 and FIG. 3, and only two flip-flop groups are shown in each clock domain. However, the multi-clock domain logic system can include one or more different clock domains, and each clock domain can include one or more flip-flop groups. In addition, the test clock signal TEST_CLK can be an independent clock signal only used for the scanning test, or can be the first clock signal CLK1 or the second clock signal CLK2.

The embodiments of the present invention disclose the method to input the scanning test signals into each flip-flop group asynchronously in a predetermined sequence, by controlling the clock skew of the clock signals of each flip-flop group. In this way, during the scanning test, different flip-flop groups operate according to the asynchronous clock signals and the instantaneous power consumption is not too large. And since the clock skew can be controlled, disadvantages of the conventional scanning test method do not occur.

Those skilled in the art will readily observe that numerous modifications and alterations of the device may be made while retaining the teachings of the invention. Accordingly, the above disclosure should be construed as limited only by the metes and bounds of the appended claims.

1. A multi-clock domain logic system comprising:
a plurality of clock domains corresponding respectively to a plurality of clock signals and comprising at least one flip-flop group per each clock domain;
wherein during a scanning test, a scanning test clock signal is asynchronously input into the clock domains in a predetermined sequence.

2. The system of claim 1, wherein the clock domains comprises a first clock domain coupled with a first clock signal, the first clock domain comprising:
a first flip-flop group that receives the first clock signal;
a second flip-flop group; and
a first logic gate group coupled with the first clock signal for generating a first logic signal,
wherein during the logic operation, the first flip-flop group receives the first clock signal as its clock signal, the second flip-flop group receives the second clock signal as its clock signal, and during the scanning test, the scanning test clock signal is asynchronously input into the first flip-flop group and the second flip-flop group in sequence to be their clock signal.

3. The system of claim 2, wherein the first clock domain further comprises:
a first delay device coupled with the scanning test clock signal for delaying the scanning test clock signal; and
a first multiplexer coupled with the first logic gate group, the first delay device, and the second flip-flop group, for selectively outputting the first logic signal or the delayed scanning test clock signal to the second flip-flop group.

4. The system of claim 2, wherein the first clock domain further comprises:
a first delay device coupled with the scanning test clock signal for delaying the scanning test clock signal; and
a first multiplexer coupled with the first delay device and the first flip-flop group, for selectively outputting the first clock signal or the delayed scanning test clock signal to the first flip-flop group.

5. The system of claim 2, wherein the first flip-flop group and the second flip-flop group are serially connected in a scan chain.

6. The multi-clock logic system of claim 1, further comprising:
a first clock domain coupled with a first clock signal comprising at least one first flip-flop group; and
a second clock domain coupled with a second clock signal comprising at least one second flip-flop group,
wherein during the scanning test, the scanning test clock signal is asynchronously input into the first flip-flop group and the second flip-flop group in sequence to be their clock signal.

7. The system of claim 6, wherein the first clock domain further comprises:
a first delay device coupled with the scanning test clock signal for delaying the scanning test clock signal; and
a first multiplexer coupled with the first delay device and the second flip-flop group, for selectively outputting the second clock signal or the delayed scanning test clock signal to the second flip-flop group.

8. The system of claim 1, wherein each flip flip-flop group comprises at least one first unit for selectively outputting a function input signal or a scan input signal.

9. The system of claim 8, wherein the first unit is a scan flip-flop.

10. The system of claim 8, wherein the first unit further comprises:
a first multiplexer for selectively outputting the function input signal or the scan input signal; and
a first flip-flop for receiving the function input signal or the scan input signal and outputting the function input signal or the scan input signal according to the corresponding clock signal.

11. The system of claim 1, wherein the scanning test clock signal is one of the clock signals.

12. A multi-clock domain logic system comprising:
a first clock domain that receives a first clock signal comprising:
a first flip-flop group that receives the first clock signal;
a second flip-flop group; and
a first delay device for outputting a first delayed scanning test clock signal; and
a second clock domain that receives a second clock signal comprising:
a third flip-flop group that receives the second clock signal; and
a second delay device for outputting a second delayed scanning test clock signal,
wherein during a scanning test, through the first delay device and the second delay device, a scanning test clock signal is asynchronously input into the first flip-flop group, the second flip-flop group and the third flip-flop group in a predetermined sequence.

13. The system of claim 12, wherein the first delayed scanning test clock signal is prior to or following the second delayed scanning test clock signal.

14. The system of claim 12, wherein the first clock domain further comprises a first logic gate group coupled with the second flip-flop group, for outputting a first logic signal according to the first clock signal; and the second flip-flop group operates according to the first logic signal when logic operation is executed.

15. The system of claim 12, wherein the scanning test clock signal is the first clock signal or the second clock signal.

16. A method of scanning test of a multi-clock domain logic system comprising:
during a logic operation, operating a first flip-flop group and a second flip-flop group according to a first clock signal or a second clock signal; and
during a scanning test, operating the first flip-flop group according to a first scanning test clock signal, and operating the second flip-flop group according to a delayed first scanning test clock signal.

17. A method of claim 16, further comprising:
delaying the first scanning test clock signal and outputting the delayed first scanning test clock signal to the second flip-flop group.
